(19) United States
(12) Patent Application Publication
(10) Pub. No.: US 2017/0324040 A1
(43) Pub. Date: Nov. 9, 2017

(54) SURFACE SEALING MATERIAL FOR ORGANIC EL ELEMENTS AND CURED PRODUCT OF SAME

(71) Applicant: Mitsui Chemicals, Inc., Minato-ku, Tokyo (JP)

(72) Inventors: Yugo YAMAMOTO, Ichihara-shi, Chiba (JP); Jun OKABE, Chiba-shi, Chiba (JP)

(73) Assignee: Mitsui Chemicals, Inc., Minato-ku, Tokyo (JP)

(21) Appl. No.: 15/525,484

(22) PCT Filed: Dec. 8, 2015
(86) PCT No.: PCT/JP2015/006084

§ 371 Date: May 9, 2017

(30) Foreign Application Priority Data
Dec. 9, 2014 (JP) 2014-249034

(51) Int. Cl. H01L 51/00; C09D 163/00; C09D 7/12; H01L 51/52; C09D 7/06

(52) U.S. Cl. CPC H01L 51/0034; H01L 51/5253; C09D 7/06; C09D 7/125; C09D 163/00

(57) ABSTRACT

The purpose of the present invention is to provide a surface sealing material which has high storage stability and is capable of forming, on an object to be coated such as an organic EL element, a cured product layer that has less irregularity, cissing and the like, while having high surface smoothness. A surface sealing material for organic EL elements according to the present invention contains (B) a cationically polymerizable compound that comprises a cationically polymerizable functional group in each molecule and has a structure represented by formula (1) —(R—O)ₙ— (wherein R represents an alkylene group having 2-5 carbon atoms and n represents an integer of 1-150), (C) a thermal cationic polymerization initiator and (D) a leveling agent.

### TECHNICAL FIELD

The present invention relates to a surface sealing agent for an organic EL element and a cured product thereof.

### BACKGROUND ART

Organic EL elements are used as backlights for liquid crystal displays and self-luminous type thin display devices. However, upon contact with moisture or oxygen, the organic EL elements are highly likely to be deteriorated. Specifically, delamination at an interface between a metal electrode and an organic EL layer by the effect of moisture, increase in resistance due to oxidization of metals, and denaturation of an organic material itself by moisture may occur. As a result, organic EL elements may suffer loss of luminescence or decreased luminance.

One of the methods for protecting organic EL elements from moisture or oxygen is surface-sealing of the organic EL element with a transparent resin layer. In the method, for example, a curable resin composition is coated on an organic EL element, followed by photocuring or thermal curing to thereby surface-seal the organic EL element. As curable resin compositions for use in the above method, proposed are, for example, a photocurable resin composition containing a photocationic polymerizable compound, a photocationic polymerization initiator, and a compound having an ether bond (curing controlling agent) (e.g., PTL 1); and a resin composition for sealing an organic EL element, which contains an epoxy compound, a polyester resin, and a Lewis acid compound (e.g., PTL 2).

As a curable resin composition for other applications, there is also known a curable epoxy resin composition containing an alicyclic epoxy compound (A), a monoallyl diglycidyl isocyanurate compound (B), a leveling agent (C), a curing agent (D) and a curing accelerator (F) (e.g., PTL 3).

### CITATION LIST

### Patent Literature

PTL 1

Japanese Patent Application Laid-Open No. 2004-231957

PTL 2

Japanese Patent Application Laid-Open No. 2014-2875

PTL 3

Japanese Patent Application Laid-Open No. 2013-18921

### SUMMARY OF INVENTION

### Technical Problem

As described above, the surface-sealing of an organic EL element is performed by coating a surface sealing agent on the organic EL element, followed by curing of the coated surface sealing agent. The curing may be photocuring or thermal curing, but thermal curing is preferred when the element is susceptible to light deterioration. However, with respect to the conventional surface sealing agents, such as those described in PTLs 1 and 2, after the coating of the surface sealing agent, irregularity and cissing are likely to occur at the surface of the coated surface sealing agents during curing, especially thermal curing, and therefore, there has been a problem such that the surface smoothness of the cured product layer is likely to be impaired.

When the cured product layer of the surface sealing agent which seals the organic EL element has only a low surface smoothness, for example, surface irregularity of the cured product layer may act as lenses, thereby causing the light output from the organic EL element to become ununiform at the surface. Further, formation of a barrier film, such as an inorganic thin film, on the cured product layer may be accompanied by occurrence of defects, such as pinholes, and therefore, obtainment of a satisfactory barrier property is difficult.

In addition, surface sealing agents are required to have high storage stability.

With the above in mind, it should be noted that, in the first place, the curable resin composition described in PTL 3 is not for use as a surface sealing agent for an organic EL element. Moreover, the composition cannot achieve high surface smoothness of the cured product layer and storage stability at the same time.

The present invention has been made in view of the above circumstances, and an object of the present invention is to provide a surface sealing agent which has high storage stability, and which can form a cured product layer on an object to be coated, such as an organic EL element, the cured product layer showing low occurrence of irregularity and cissing and having high surface smoothness.

### Solution to Problem

[1] A surface sealing agent for an organic EL element, comprising:

(B) a cationic polymerizable compound having a cationic polymerizable functional group per molecule, and also having a structure represented by following formula (1):

—(R—O)ₙ— Formula (1)
wherein:
R represents an alkylene group having 2 to 5 carbon atoms and
n represents an integer of 1 to 150;

(C) a thermal cationic polymerization initiator; and

(D) a leveling agent.

[2] The surface sealing agent for an organic EL element according to [1], wherein the component (B) is represented by formula (1) in which R is an ethylene group and n is 2 or more.

[3] The surface sealing agent for an organic EL element according to [1], wherein weight average molecular weight of the component (B) is 250 to 10,000.

[4] The surface sealing agent for an organic EL element according to [1], further comprising:

(A1) a cationic polymerizable compound (exclusive of the component (B)) having two or more cationic polymerizable functional groups per molecule.

[5] The surface sealing agent for an organic EL element according to [4], wherein the component (A1) has a bisphenol structure.

[6] The surface sealing agent for an organic EL element according to [4], comprising 0.1 to 120 parts by mass of the component (B), based on 100 parts by mass of the component (A1).

[7] The surface sealing agent for an organic EL element according to [4], comprising:

0.1 to 5 parts by mass of the component (C), and

0.01 to 1 part by mass of the component (D),

each based on 100 parts by mass of a total of the components (A1) and (B).

[8] The surface sealing agent for an organic EL element according to any one of [1] to [3], wherein: the component (B) is (B1) a cationic polymerizable compound having two or more cationic polymerizable functional groups per molecule, and

the surface sealing agent optionally comprises (A) a cationic polymerizable compound (exclusive of the component (B)) having a cationic polymerizable functional group per molecule.

[9] The surface sealing agent for an organic EL element according to [8], wherein the component (B1) has a bisphenol structure.

[10] The surface sealing agent for an organic EL element according to [8] or [9], comprising 0.1 to 120 parts by mass of the component (A), based on 100 parts by mass of the component (B1).

[11] The surface sealing agent for an organic EL element according to any one of [8] to [10], comprising:

0.1 to 5 parts by mass of the component (C), and

0.01 to 1 parts by mass of the component (D),

each based on 100 parts by mass of a total of the components (B1) and (A).

[12] The surface sealing agent for an organic EL element according to any one of [1] to [11], wherein the component (D) is at least one member selected from the group consisting of a silicone-based polymer and an acrylate-based polymer.

[13] The surface sealing agent for an organic EL element according to any one of [1] to [12], wherein the cationic polymerizable functional group is at least one member selected from the group consisting of an epoxy group, an oxetanyl group and a vinyl ether group.

[14] The surface sealing agent for an organic EL element according to any one of [1] to [13], wherein the component (C) is an onium salt.

[15] The surface sealing agent for an organic EL element according to any one of [1] to [14] having a viscosity of 50 to 30,000 mPa·s, as measured by an E-type viscometer at 25° C. and 2.5 rpm.

[16] The surface sealing agent for an organic EL element according to any one of [1] to [15] which is in a sheet form.

[17] A cured product of the surface sealing agent for an organic EL element according to any one of [1] to [16].

### Advantageous Effects of Invention

The present invention can provide a surface sealing agent which has satisfactory storage stability, and which can form a cured product layer on an object to be coated, such as an organic EL element. The formed cured product layer shows low occurrence of irregularity and cissing and has high surface smoothness.

### BRIEF DESCRIPTION OF DRAWINGS

FIG. 1 is a schematic view illustrating an example of an organic EL device;

FIG. 2A is a schematic view illustrating an example of a process for manufacturing an organic EL device;

FIG. 2B is a schematic view illustrating an example of the process for manufacturing an organic EL device; and

FIG. 2C is a schematic view illustrating an example of the process for manufacturing an organic EL device.

### DESCRIPTION OF EMBODIMENTS

The present inventors have found, in the former study, that a thermosetting composition containing a cationic polymerizable compound (A), a polyether compound (b), a thermal cationic polymerization initiator (C), and a leveling agent (D) can provide a cured product having high surface smoothness. Particularly, presence of a polyether compound (b) having a large molecular weight enables the obtainment of a cured product having high surface smoothness. However, the polyether compound (b) having a large molecular weight has low compatibility with the cationic polymerizable compound (A) and, therefore, storage stability of the thermosetting composition was unsatisfactory.

The present inventors have now found that, using “a cationic polymerizable compound (B) having a (poly)oxyalkylene structure” in place of the polyether compound (b) or a mixture of the polyether compound (b) and the cationic polymerizable compound (A) may satisfactorily increase the surface smoothness of the cured product without impairing storage stability.

The reason for the above advantages is not clear, but it is presumed as follows. During thermal curing of the composition, (poly)oxyalkylene structural moieties in the cationic polymerizable compound (B) having a (poly)oxyalkylene structure scavenge the thermal cationic polymerization initiator (C), thereby delaying the polymerization of the cationic polymerizable compound (A) or the polymerization of the cationic polymerizable compound (B) having a (poly)oxyalkylene structure. It can be presumed that the leveling agent (D) can satisfactorily exhibit its function during this delay and, therefore, it becomes possible to obtain a cured product having high surface smoothness.

Further, the cationic polymerizable compound (B) having a (poly)oxyalkylene structure has a structure similar to that of the cationic polymerizable compound (A), and therefore, it is highly compatible with the cationic polymerizable compound (A). Further, since the cationic polymerizable compound (B) having a (poly)oxyalkylene structure per se functions as a cationic polymerizable compound, other cationic polymerizable compound (A) is not necessary in the composition. From the above reasons, it becomes possible to achieve high storage stability by suppressing compatibility defect between the cationic polymerizable compound (B) having a (poly)oxyalkylene structure and the cationic polymerizable compound (A) and the precipitation resulting therefrom.

The surface sealing agent of the present invention, therefore, contains a cationic polymerizable compound (B) having a (poly)oxyalkylene structure, a thermal cationic polymerization initiator (C) and a leveling agent (D), and may further contain, as necessary, a cationic polymerizable compound (A) other than the compound (B).

1. Surface Sealing Agent

The surface sealing agent of the present invention contains a cationic polymerizable compound (B) having a (poly)oxyalkylene structure, a thermal cationic polymerization initiator (C) and a leveling agent (D), and may further contain a cationic polymerizable compound (A) as necessary.

<(B) Cationic Polymerizable Compound Having (Poly)Oxyalkylene Structure>

A cationic polymerizable compound (B) having a (poly)oxyalkylene structure is a compound having a cationic polymerizable functional group per molecule, and also having a structure ((poly)oxyalkylene structure) represented by the following formula (1):

—(R—O)ₙ—. Formula (1)

In formula (1), R represents an alkylene group having 2 to 5 carbon atoms, preferably an alkylene group having 2 to 3 carbon atoms. Examples of the alkylene groups include ethylene group and propylene group, and ethylene group is preferred.

In formula (1), n represents an integer of 1 to 150, preferably an integer of 2 to 100, and more preferably an integer of 2 to 25. The larger the value of n, the larger is the number of (poly)oxyalkylene moieties of the component (B) lined up in a manner such that unpaired electrons of the oxygen atoms in the moieties are facing inside, and such an arrangement enables the component (B) to surround the active species of the thermal cationic polymerization initiator (C). The resultant steric hindrance is considered to reduce the probability of contact between the active species of the thermal cationic polymerization initiator (C) and the cationic polymerizable compound, such as the component (B) and the component (A). That is, it is considered that, by suitably elongating the time needed for the active species of the thermal cationic polymerization initiator (C) to get into first contact with the cationic polymerizable compound, such as the component (B) and the component (A), it becomes possible for the leveling agent (D) to satisfactorily exhibit its function before the first contact.

Number of structure(s) represented by formula (1) may be one per molecule, or more than one per molecule. When more than one structures represented by formula (1) are contained per molecule, the structures may be the same or different. For example, the component (B) may contain, per molecule, a (poly)oxyethylene structure (—CH₂CH₂O—)ₙ and a (poly)oxypropylene structure (—CH₂CH₂CH₂O—)ₙ, or two or more (poly)oxyethylene structures (—CH₂CH₂O—)ₙ. Further, when a plurality of the structures represented by formula (1) are contained per molecule, the numbers (n's) of the recurring units represented by formula (1) may be the same or different.

The cationic polymerizable functional group contained in the cationic polymerizable compound (B) having a (poly)oxyalkylene structure is an epoxy group, an oxetanyl group or a vinyl ether group, and may preferably be an epoxy group. The number of cationic polymerizable functional group(s) per molecule is 1, or 2 or more. When a plurality of cationic polymerizable functional groups are present per molecule, the groups may be the same or different.

The cationic polymerizable compound (B) having a (poly)oxyalkylene structure may preferably be a glycidyl ether, oxetanyl ether or vinyl ether of a polyalkylene oxide poly(mono)ol. The polyalkylene oxide poly(mono)ol may be an aliphatic polyalkylene oxide poly(mono)ol, or an aromatic polyalkylene oxide poly(mono)ol.

Examples of the aliphatic polyalkylene oxide poly(mono)ols include alkylene oxide (AO) adducts of aliphatic alcohols, such as methanol, ethanol, propanol and lauryl alcohol; polyethylene glycol; polypropylene glycol; and polyoxytetramethylene glycol.

Examples of the aromatic polyalkylene oxide poly(mono)ols include an alkylene oxide (AO) adduct of phenol, and alkylene oxide (AO) adducts of bisphenols (e.g., bisphenol A, bisphenol F and bisphenol E).

Specific examples of the glycidyl ethers of polyalkylene oxide poly(mono)ols include compounds represented by the following formulas (2) to (4). The compound represented by formula (4) is preferably a compound represented by formula (4′).

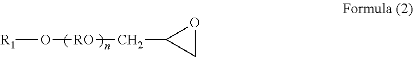

In formula (2), the definitions of R and n may be the same as those of formula (1). R₁ may be an alkyl group having 1 to 18 carbon atoms or an aryl group having 6 to 20 carbon atoms. Examples of the alkyl groups include lauryl group, methyl group, ethyl group and propyl group, and examples of the aryl groups include phenyl group and naphthyl group.

Specific examples of the compounds represented by formula (2) include phenol (EO)ₙ, glycidyl ether, and lauryl alcohol (EO)ₙ glycidyl ether.

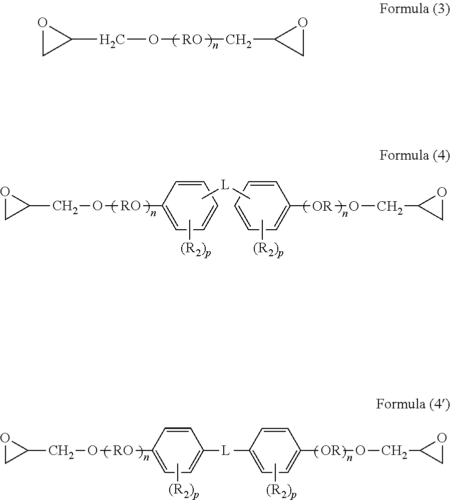

In formulas (3), (4) and (4′), the definitions of R and n may be the same as those of formula (1). L in formulas (4) and (4′) is a divalent linking group, and specific examples include —(CH₃)₂C—, —CH₂— or —CH(CH₃)—. In formulas (4) and (4′), each R₂ independently represents an alkyl group having 1 to 5 carbon atoms, and each p represents an integer of 0 to 4.

Specific examples of the compounds represented by formula (3) include ethylene glycol diglycidyl ether, polyethylene glycol diglycidyl ether, propylene glycol diglycidyl ether and polypropylene glycol diglycidyl ether. Specific examples of the compounds represented by formulas (4) and (4′) include bisphenol A bis(triethylene glycol glycidyl ether) ether.

Specific examples of the oxetanyl ethers of polyalkylene oxide poly(mono)ols include ethylene glycol dioxetanyl ether, polyethylene glycol dioxetanyl ether, propylene glycol dioxetanyl ether, polypropylene glycol dioxetanyl ether, and bisphenol A bis(triethylene glycol oxetanyl ether) ether.

Specific examples of the vinyl ethers of polyalkylene oxide poly(mono)ols include ethylene glycol divinyl ether, polyethylene glycol divinyl ether, propylene glycol divinyl ether, polypropylene glycol divinyl ether, and bisphenol A bis(triethylene glycol divinyl ether) ether.

Among the above compounds, the glycidyl ethers of polyalkylene oxide poly(mono)ols are preferred due to their satisfactory polymerization reactivity. The glycidyl ethers of aromatic polyalkylene oxide poly(mono)ols are more preferred, the glycidyl ethers of polyalkylene oxide poly(mono)ols having a bisphenol structure are still more preferred, and a compound represented by formula (4) or (4′) is even more preferred, due to their high compatibility with a bisphenol type epoxy compound generally used as the cationic polymerizable compound (A).

For increasing the polymerization reactivity, a cationic polymerizable compound (B1) having two or more cationic polymerizable functional groups per molecule is preferred.

The weight average molecular weight of the cationic polymerizable compound (B) having a (poly)oxyalkylene structure is preferably 250 to 10,000, more preferably 400 to 10,000, and even more preferably 400 to 6,000. When the weight average molecular weight of the component (B) is above a predetermined value, the (poly)oxyalkylene structure is more likely to satisfactorily scavenge cations of the thermal cationic polymerization initiator (C) because it contains sufficient amount of the structure per molecule of the component (B). As a result, the flow time of the surface sealing agent during the thermal curing can be prolonged, and the leveling agent (D) is more likely to satisfactorily exhibit its function during the prolonged flow time. When the weight average molecular weight of the component (B) is below a predetermined value, solubility of the component (B) in the surface sealing agent is less likely to become lowered, and the viscosity of the surface sealing agent is less likely to become increased.

The weight average molecular weight (MW) of the component (B) can be measured by gel permeation chromatography (GPC) using polystyrene as a standard reference material.

With respect to the cationic polymerizable compound (B) having a (poly)oxyalkylene structure, the cationic polymerizable functional group equivalent weight is preferably 250 to 1,500 g/eq. By controlling the cationic polymerizable functional group equivalent weight to a value below a predetermined value, satisfactory flowability can be obtained without impairing polymerization reactivity.

The cationic polymerizable compound (B) having a (poly)oxyalkylene structure may be the main component of the cationic polymerizable compound, or an accessory component to be combined with a cationic polymerizable compound (A) described below.

<(A) Cationic Polymerizable Compound>

Cationic polymerizable compound (A) is a compound having a cationic polymerizable functional group per molecule. However, the cationic polymerizable compound (A) is different from the component (B), and does not have a polyoxyalkylene structure, i.e., a structure represented by formula (1).

The cationic polymerizable functional group contained in the cationic polymerizable compound (A) is an epoxy group, an oxetanyl group or a vinyl ether group, and preferably an epoxy group. The number of cationic polymerizable functional group(s) per molecule is 1, or 2 or more. When a plurality of cationic polymerizable functional groups are present per molecule, the groups may be the same or different. The cationic polymerizable functional group contained in the component (A) may be the same as or different from the cationic polymerizable functional group contained in the component (B).

Examples of the epoxy compounds having one epoxy group per molecule include aromatic epoxy compounds, such as para-tertiary butylphenyl glycidyl ether and phenyl glycidyl ether, and aliphatic epoxy compounds, such as 2-ethylhexyl glycidyl ether.

Examples of the epoxy compounds having two or more epoxy groups per molecule include bisphenol type epoxy compounds, such as a bisphenol A type epoxy compound, a bisphenol F type epoxy compound, a bisphenol E type epoxy compound, a bisphenol S type epoxy compound and a bisphenol AD type epoxy compound; diphenyl ether type epoxy compounds; novolak type epoxy compounds, such as a phenol novolak type epoxy compound, a cresol novolak type epoxy compound, a biphenyl novolak type epoxy compound, a bisphenol novolak type epoxy compound, a naphthol novolak type epoxy compound, a trisphenol novolak type epoxy compound, a dicyclopentadiene novolac type epoxy compound; biphenyl type epoxy compounds; naphthalene type epoxy compounds; aromatic epoxy compounds, such as a triphenolalkane type epoxy compound of a triphenolmethane type, triphenol ethane type or a triphenol propane type; alicyclic epoxy compounds, such as a hydrogenated bisphenol A type epoxy compound; and aliphatic epoxy compounds, such as a dicyclopentadiene type epoxy compound and a cyclohexanedimethanol type epoxy compound.

Examples of the oxetanyl compounds having two or more oxetanyl groups per molecule include aromatic oxetane compounds, such as 1,3-bis[(3-ethyl-3-oxetanyl) methoxy] benzene and 1,4-bis{[(3-ethyl-3-oxetanyl) methoxy] methyl} benzene; alicyclic oxetane compounds, such as 1,4-bis{[(3-ethyl-3-oxetanyl) methoxy] methyl} cyclohexane and 4,4′-bis{[(3-ethyl-3-oxetanyl) methoxy] methyl} bicyclohexane; and aliphatic oxetane compounds, such as di[1-ethyl (3-oxetanyl)] methyl ether, bis(3-ethyl-3-oxetanylmethyl) ether, trimethylolpropane tris(3-ethyl-3-oxetanylmethyl) ether and pentaerythritol tris(3-ethyl-3-oxetanylmethyl) ether.

Examples of the vinyl ether compounds having two or more vinyl ether groups per molecule include alicyclic vinyl ether compounds, such as cyclohexanedimethanol divinyl ether.

Among the above compounds, a cationic polymerizable compound (A1) having two or more cationic polymerizable functional groups per molecule is preferred for increasing polymerization reactivity.

As the cationic polymerizable compound (A1) having two or more cationic polymerizable functional groups per molecule, for easily adjusting the viscosity of the surface sealing agent to fall within a later-described range, preferred is a cationic polymerizable compound in a liquid form at 25° C., and for surface sealing agent to easily obtain adhesiveness to an object to be coated, preferred is an epoxy compound having two or more epoxy groups per molecule. As the epoxy compound having two or more epoxy groups per molecule, an aromatic epoxy compound is preferred for easily increasing moisture resistance of the cured product.

The aromatic epoxy compound is preferably a bisphenol type epoxy compound, cresol novolak type epoxy compound or the like, and more preferably a bisphenol type epoxy compound. The bisphenol type epoxy compound is preferably a compound represented by general formula (X), and preferred examples of such compounds include a compound represented by general formula (X′).

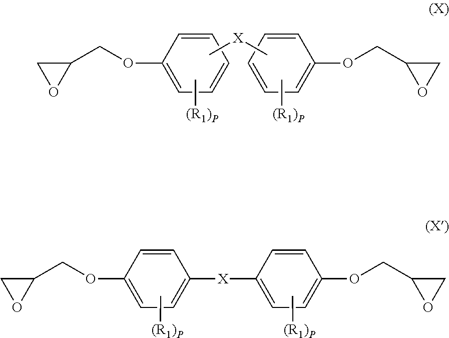

In general formulas (X) and (X′), X represents a single bond, methylene group, isopropylidene group, —S— or —SO₂—, each R₁ independently represents an alkyl group having 1 to 5 carbon atoms, and each p independently represents an integer of 0 to 4.

The cationic polymerizable compound (A) is preferably a low-molecular weight compound for easily adjusting the viscosity of the surface sealing agent to fall within a later-described range, and for easily ensuring satisfactory flowability during coating or curing. Specifically, the weight average molecular weight of the cationic polymerizable compound is preferably 200 to 800, and more preferably 300 to 700. The weight average molecular weight (Mw) of the component (A) can be measured in the same manner as described above.

The cationic polymerizable functional group equivalent weight of the cationic polymerizable compound (A) is preferably 100 to 800 g/eq.

On the other hand, for easily forming a sheet from the surface sealing agent, the cationic polymerizable compound (A) may further contain, as necessary, a high-molecular weight cationic polymerizable compound. The weight average molecular weight (Mw) of the high-molecular weight cationic polymerizable compound is preferably 3×10³ to 2×10⁴ and more preferably 3×10³ to 7×10³.

<Combination of Component (B) and Component (A)>

When the component (B) is the main component of the cationic polymerizable compound, from the viewpoint of increasing polymerization reactivity, the component (B) is preferably “a cationic polymerizable compound (B1) having two or more cationic polymerizable functional groups per molecule.” When the component (A) is the main component of the cationic polymerizable compound, from the viewpoint of increasing polymerization reactivity, the component (A) is preferably “a cationic polymerizable compound (A1) having two or more cationic polymerizable functional groups per molecule.” In the present invention, the “main component” is a component having the highest mass ratio in the surface sealing agent.

That is, the surface sealing agent preferably contains either: a cationic polymerizable compound (A1) having two or more cationic polymerizable functional groups per molecule, and a cationic polymerizable compound (B) having a cationic polymerizable functional group per molecule and also having a (poly)oxyalkylene structure (first surface sealing agent); or a cationic polymerizable compound (B1) having two or more cationic polymerizable functional groups per molecule and also having a (poly)oxyalkylene structure, and, as necessary, a cationic polymerizable compound (A) having a cationic polymerizable functional group per molecule (second surface sealing agent). The components (B) and (B1) preferably have a bisphenol structure per molecule for increasing their compatibility with a bisphenol type epoxy compound which is generally used as a cationic polymerizable compound (A).

It is preferred that the content of the component (B) is determined in accordance with the content (molar amount) of the thermal cationic polymerization initiator (C). Specifically, by preventing the content of the thermal cationic polymerization initiator (C) from being an excessive amount, relative to the component (B), satisfactory polymerization delaying effect is more easily obtained.

The content of the component (B) in the first surface sealing agent is preferably 0.1 to 100 parts by mass based on 100 parts by mass of the component (A1). When the component (B) has a bisphenol structure, the content of the component (B) is preferably 1 to 100 parts by mass based on 100 parts by mass of the component (A1). When the component (B) does not have a bisphenol structure, the content of the component (B) is preferably 0.1 to 20 parts by mass based on 100 parts by mass of the component (A1).

When the content of the component (B) is above a predetermined value, the component (B) is more likely to satisfactorily scavenge cations of the thermal cationic polymerization initiator (C) by its ether bond moieties, and the polymerization delaying effect of the cationic polymerizable compound, such as the component (B) and the component (A), is achieved more easily. As a result, satisfactory leveling of the surface sealing agent becomes easy. On the other hand, when the content of the component (B) is below a predetermined value, the component (B) can satisfactorily dissolve in the surface sealing agent, and further, the surface sealing agent does not easily solidify during storage at normal temperature, and therefore, the storage stability of the surface sealing agent is less likely to be impaired.

The content of the component (A) in the second surface sealing agent is preferably 0.1 to 100 parts by mass based on 100 parts by mass of the component (B1).

From the viewpoint of satisfactorily performing the curing reaction, the total content of the components (B) and (A) may preferably be 60 mass % or more, more preferably 70 mass % or more, and still more preferably 80 mass % based on the surface sealing agent. In the present invention, “the total of the components (B) and (A)” is the total of the components (B) and (A1) in the first surface sealing agent, and the total of the components (B1) and (A) in the second surface sealing agent.

<(C) Thermal Cationic Polymerization Initiator>

A thermal cationic polymerization initiator is a compound which generate cationic species initiating polymerization upon heating. There is no particular limitation with respect to the thermal cationic polymerization initiator, and it can be appropriately selected according to the curing condition or the type of the cationic polymerizable compound. For example, when the cationic polymerizable compound is an epoxy compound, the thermal cationic polymerization initiator may be an onium salt, such as a quaternary ammonium salt or a phosphonium salt.

Among the above compounds, in view of the increase in the storage stability of the surface sealing agent, or the suppression of discoloration of the cured product, the quaternary ammonium salt is preferred. An example of the quaternary ammonium salt include a salt (C1) having a specific quaternary ammonium ion and a counter anion.

The quaternary ammonium ion constituting the salt (C) can be represented by the following formula (5):

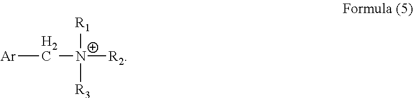

In formula (5), R₁, R₂, and R₃ each represents a substituted or unsubstituted alkyl group having 1 to 10 carbon atoms, a substituted or unsubstituted aryl group having 6 to 10 carbon atoms, or a substituted or unsubstituted aralkyl group having 7 to 20 carbon atoms. In particular, each of R₁, R₂, and R₃ is preferably a methyl group, a phenyl group, or a benzyl group.

There is no particular limitation with respect to a substituent attached to R₁, R₂, and R₃, but it is preferably a functional group selected from the group consisting of an alkyl group having 1 to 10 carbon atoms, an alkoxy group having 1 to 10 carbon atoms, —F, —Cl, —Br, —I, —NO₂, —CN, and a group represented by the following formula (6):

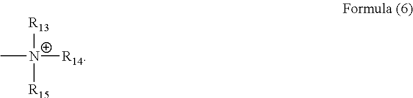

In formula (6), R₁₃, R₁₄, and R₁₅ each represents a hydrogen group or a hydrocarbon group having 1 to 10 carbon atoms. In view of, for example, the increase in storage stability of the surface sealing agent, each of R₁₃, R₁₄, and R₁₅ is preferably a hydrocarbon group. The hydrocarbon group may be a linear, branched or cyclic aliphatic group, or an aromatic group.

In formula (5), Ar represents a substituted or unsubstituted aryl group having 6 to 10 carbon atoms. Ar is preferably an aromatic hydrocarbon group, and may be, for example, a phenyl group or a naphthyl group. There is no particular limitation with respect to a substituent attached to Ar in formula (5), and it may be the same as that optionally attached to R₁, R₂, and R₃ in formula (5).

The bonding position or number of substituents bonded to Ar is not particularly limited. For example, when the substituent bonded to Ar is an electron acceptor, for example, —F, —Cl, —Br, —I, —NO₂, or —CN, the substituent is preferably bonded to a meta- or para-position, relative to the bonding position of the Ar to the methylene group in formula (5). When the electron acceptor is bonded to the above-mentioned position, the curing reaction of the cationic polymerizable compound becomes easily accelerated. The number of the electron acceptor(s) bonded to Ar is preferably 2 or less.

On the other hand, when the substituent bonded to Ar is an electron donor, for example, an alkyl group, an alkoxy group, or a group represented by formula (6), the substituent is preferably bonded to a para-position, relative to the bonding position of the Ar to the methylene group in formula (5). When the electron donor is bonded to this position, the curing reaction of the cationic polymerizable compound becomes easily accelerated. Such an acceleration of the curing reaction of the cationic polymerizable compound is easier when the Ar-bonded substituent is an electron donor, as compared to a case where the Ar-bonded substituent is an electron acceptor.

Preferred examples of the quaternary ammonium ions represented by formula (5) include the ions below.

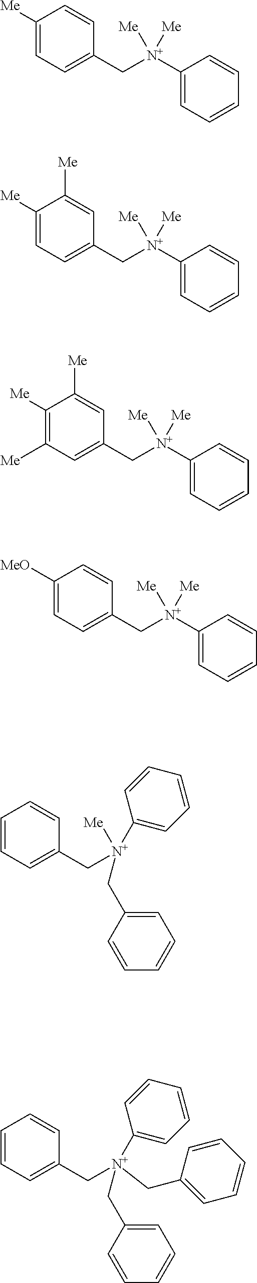 [SMILES: Cc1ccc(C[N+](C)(C)c2ccccc2)cc1 ; Cc1ccc(C[N+](C)(C)c2ccccc2)cc1C ; Cc1cc(C[N+](C)(C)c2ccccc2)cc(C)c1C ; COc1ccc(C[N+](C)(C)c2ccccc2)cc1 ; C[N+](Cc1ccccc1)(Cc1ccccc1)c1ccccc1 ; c1ccc(C[N+](Cc2ccccc2)(Cc2ccccc2)c2ccccc2)cc1]

Examples of the counter anions constituting the salt (C) include [CF₃SO₃]⁻, [C₄F₉SO₃]⁻, [PF₆]⁻, [AsF₆]⁻, [Ph₄B]⁻, Cl⁻, Br⁻, I⁻, [OC(O)R₁₆]⁻ (where R₁₆ represents an alkyl group having 1 to 10 carbon atoms), [SbF₆]⁻, [B(C₆F₅)₄]⁻, [B(C₆H₄CF₃)₄]⁻, [(C₆F₅)₂BF₂]⁻, [C₆F₅BF₃]⁻, and [B(C₆H₃F₂)₄]⁻. Among the above anions, preferred is an anion having a small logarithmic value of a reciprocal of an acid dissociation constant (pKa). The smaller the pKa, the more easier is the ionization of the salt (C1), which in turn accelerates the curing reaction of the epoxy resin.

Preferred examples of the salts (C1) include the compounds below.

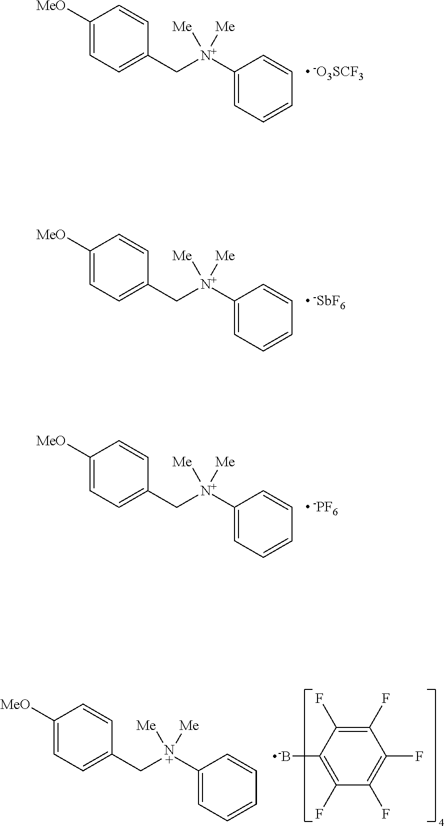

When the salt (C1) is heated to or above a predetermined temperature, a proton at a benzylic position of the quaternary ammonium ion becomes dissociated, and a proton is donated to a cationic polymerizable functional group of the cationic polymerizable compound, for example, to an epoxy group of the epoxy compound. In the epoxy compound receiving the donated proton, ring opening of the epoxy group occurs, thereby effecting a polymerization with plurality of other epoxy compounds, followed by curing. In this manner, the salt (C1) can initiate polymerization of the epoxy compound upon heating to or above a predetermined temperature. On the other hand, such a reaction is difficult to occur at a low temperature, and therefore, the storage stability of the surface sealing agent becomes improved.

The reactivity of the quaternary ammonium ion can be adjusted by a substituent attached to the aryl group adjacent to the methylene group. For example, using an electron donor as the substituent of the aryl group can increase the reactivity of the quaternary ammonium ion.

The content of the thermal cationic polymerization initiator (C) is preferably 0.1 to 5 parts by mass, and more preferably 0.1 to 3 parts by mass based on 100 parts by mass of the total of the components (B) and (A). When the content of thermal cationic polymerization initiator is above a predetermined value, sufficient curing of the cationic polymerizable compounds, such as component (B) and component (A), becomes easy. On the other hand, when the content of thermal cationic polymerization initiator is below a predetermined value, not only the stability of the surface sealing agent during storage is less likely to be impaired, but also the heat resistance or the like of the cured product is less likely to be impaired due to reduced amount of the residual unreacted thermal cationic polymerization initiator in the cured product. The thermal cationic polymerization initiator may be composed of a single compound or a combination of two or more compounds.

The ratio (equivalent ratio) of the amount of ammonium ions in the thermal cationic polymerization initiator to the amount of cationic polymerizable functional groups contained in the surface sealing agent (i.e., (the number of ammonium ions in the thermal cationic polymerization initiator/the number of cationic polymerizable functional groups in the surface sealing agent)×100) is preferably 0.5 to 10%, and more preferably 0.5 to 1%.

<(D) Leveling Agent>

During thermal curing of the surface sealing agent, the leveling agent is oriented on the surface of the coated surface sealing agent and uniformizes the surface tension of the resultant coating film, thereby lowering the occurrence of cissing and enabling satisfactory wet-spreading on an object to be coated. Therefore, the leveling agent is preferably selected so as to satisfy the following relationship,

S=γv−γA−γI>0

(S: spreading coefficient, γv: surface tension of coating film of surface sealing agent, γA: surface tension of leveling agent, γI: interfacial tension between surface sealing agent and leveling agent).

The leveling agent may be selected so that its surface tension (γA) is smaller than the surface tension (γv) of the coating film of the surface sealing agent during the thermal curing thereof, and that the interfacial tension (γI) between the surface sealing agent and the leveling agent is also small. For achieving a satisfactory leveling effect by adding only a small amount of the leveling agent, the leveling agent is preferably not compatible with the cationic polymerizable compound.

The leveling agent is capable of improving the wettability of the surface sealing agent to an object to be coated by adjusting the surface tension of the coating film surface, and smoothing the surface of the coating film by improving the flowability and defoaming properties of the coating film surface. Such effects are frequently achieved by adding only a small amount of the leveling agent. Therefore, a silicone-based or acrylate-based polymer, which has a smaller surface-modification function than a fluorine-based polymer, is preferred as the leveling agent.

The silicone-based polymer is preferably a polymer having a polydimethylsiloxane derived structure represented by the following formula, in which n is preferably 2 or more, and more preferably 2 to 140.

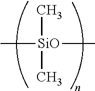

Examples of the silicone-based polymers include polydimethylsiloxane, polyether modified polydimethylsiloxane and polymethylalkylsiloxane.

The acrylate-based polymer is preferably a polymer of monomers containing an alkyl acrylate. The number of carbon atoms of the alkyl chain in the alkyl acrylate is preferably 4 or more, and more preferably 6 or more. The upper limit of the number of carbon atoms of the alkyl chain in the alkyl acrylate may be, for example, 12. Examples of the alkyl acrylates include butyl acrylate and 2-ethylhexyl acrylate. It is preferred that the acrylate-based polymer does not contain fluorine atom. The alkyl acrylate used may be a single compound or a combination of two or more compounds.

An example of the acrylate-based polymer is a copolymer of butyl acrylate and 2-ethylhexyl acrylate.

The molecular weight of the silicone-based polymer or acrylate-based polymer may be about 1,000 to 10,000. When the molecular weight is above a predetermined value, the leveling agent is less likely to bleedout from a cured product. On the other hand, when the molecular weight is below a predetermined value, the leveling agent is more likely to be oriented on the coating film surface of the surface sealing agent, thereby achieving a satisfactory leveling effect.

The content of the leveling agent (D) is preferably 0.01 to 1 part by mass, and more preferably 0.05 to 0.5 parts by mass, based on 100 parts by mass of the total of the components (B) and (A). When the content of the leveling agent (D) is above a predetermined value, a satisfactory amount of the leveling agent is more likely to be oriented on the coating film surface of the surface sealing agent, thereby achieving a satisfactory leveling effect. On the other hand, when the content of the leveling agent (D) is below a predetermined value, the compatibility between the leveling agent (D) and the cationic polymerizable compounds, such as component (B) and component (A), and the transparency of the cured product are less likely to be impaired.

<(E) Other Components>

The surface sealing agent may contain other components (E) as long as the effect of the present invention is not impaired. Examples of the other components include other resin component exclusive of the above-mentioned components (A) and (B), a coupling agent, a filler, a modifier, an antioxidant, a stabilizer, and a solvent.

Examples of other resin components include a cationic polymerizable compound in a solid form (e.g., epoxy resin in a solid form), a polyamide, a polyamideimide, a polyurethane, a polybutadiene, a polychloroprene, a polyether, a polyester, a styrene-butadiene-styrene block copolymer, a petroleum resin, a xylene resin, a ketone resin, a cellulose resin, a fluorine-based oligomer, a silicon-based oligomer, and a polysulfide-based oligomer. These other resin components may be contained in the surface sealing agent individually or in combination.

Examples of the coupling agents include a silane coupling agent, a titanium-based coupling agent, a zirconium-based coupling agent, and an aluminum-based coupling agent. The coupling agent may increase adhesion of the surface sealing agent to the substrate of an organic EL device, etc.

Examples of the silane coupling agents include 1) a silane coupling agent having an epoxy group, 2) a silane coupling agent having a functional group capable of reacting with an epoxy group, and 3) other silane coupling agents. For preventing a low-molecular weight component from remaining in the cured film, the silane coupling agent is preferably a silane coupling agent which reacts with an epoxy resin in the surface sealing agent. The silane coupling agent which reacts with an epoxy resin is preferably 1) a silane coupling agent having an epoxy group, or 2) a silane coupling agent having a functional group capable of reacting with an epoxy group. The phrase “reacting with an epoxy group” refers to, for example, undergoing addition reaction with an epoxy group.

Examples of the silane coupling agents 1) having an epoxy group include γ-glycidoxypropyltrimetoxysilane and β-(3,4-epoxycyclohexyl)ethyl trimethoxysilane. Examples of the functional groups 2) capable of reacting with an epoxy group include amino groups, such as a primary amino group and a secondary amino group; carboxyl groups; and also other groups which can be converted into functional groups capable of reacting with an epoxy group (e.g., methacryloyl group, and isocyanate group). Examples of the silane coupling agents having such a functional group capable of reacting with an epoxy group include N-2-(aminoethyl)-3-aminopropylmethyldimethoxysilane and N-2-(aminoethyl)-3-aminopropylmethyltrimethoxysilane. Examples of the other silane coupling agents 3) include vinyltriacetoxysilane and vinyltrimetoxysilane. These silane coupling agents may be contained in the surface sealing agent individually or in combination.

The molecular weight of the silane coupling agent is preferably 80 to 800. When the molecular weight of the silane coupling agent exceeds 800, adhesion may be decreased.

The content of the silane coupling agent is preferably 0.05 to 30 parts by mass, more preferably 0.1 to 20 parts by mass, and still more preferably 0.3 to 10 parts by mass based on 100 parts by mass of the surface sealing agent.

Examples of the fillers include glass beads, styrene-based polymer particles, methacrylate-based polymer particles, ethylene-based polymer particles, and propylene-based polymer particles. Examples of the modifiers include a polymerization initiation auxiliary, an antiaging agent, a surfactant, and a plasticizer. Examples of the stabilizers include an ultraviolet absorber, a preservative, and an antibacterial agent.

The antioxidant refers to an agent which deactivates radicals generated by plasma irradiation or sunlight irradiation (such as a Hindered Amine Light Stabilizer, HALS), an agent which decomposes a peroxide, or the like. A cured product of a surface sealing agent containing the antioxidant may exhibit suppressed discoloration.

Examples of the antioxidants include Tinuvin 123 (bis(1-octyloxy-2,2,6,6-tetramethyl-4-piperidyl)sebacate), and Tinuvin 765 (a mixture of bis(1,2,2,6,6-pentamethyl-4-piperidyl) sebacate and methyl 1,2,2,6,6-pentamethyl-4-piperidyl sebacate).

The solvent may uniformly disperse or dissolve each component therein. The solvent is an organic solvent, and examples thereof include ketone solvents, such as acetone, methyl ethyl ketone and methyl isobutyl ketone; ethers, such as ethylene glycol monoalkyl ether, ethylene glycol dialkyl ether and propylene glycol dialkyl ether; aprotic polar solvents, such as N-methyl pyrrolidone; and esters, such as ethyl acetate and butyl acetate.

<Physical Properties of Surface Sealing Agent>

The viscosity of the surface sealing agent of the present invention as measured by an E-type viscometer at 25° C. and 2.5 rpm may be preferably 50 to 30,000 mPa·s, more preferably 100 to 10,000 mPa·s and still more preferably 500 to 6,000 mPa·s. When the viscosity of the surface sealing agent is within the above range, coatability (for example, screen printability) becomes increased. The viscosity of the surface sealing agent is measured by an E-type viscometer (RC-500, manufactured by Toki Sangyo Co., Ltd.) at 25° C. and 2.5 rpm.

The surface sealing agent may be, for example, formed into a sheet. The thickness of the sheet varies according to the application, but it may be, for example, about 0.1 to 20 μm. Such a formed product can be obtained by, for example, drying the coating film of the surface sealing agent.

The water content of the surface sealing agent is preferably 0.1 mass % or less, and more preferably 0.06 mass % or less. Since organic EL elements are liable to deterioration by moisture, the water content of the surface sealing agent is preferably minimized as much as possible. The water content of the surface sealing agent is determined by weighing about 0.1 g of a sample, heating the same at 150° C. with a Karl Fischer moisture meter, and measuring the content of moisture produced during the heating (solid evaporation method).

The reaction activity-development temperature of the surface sealing agent is appropriately adjusted depending on the heat-resistant temperature of the element to be surface-sealed, and is preferably 70 to 150° C., more preferably 80 to 110° C., and still more preferably 90 to 100° C. The reaction activity-development temperature is closely related to the curable temperature of the surface sealing agent. When the reaction activity-development temperature is 150° C. or less, the surface sealing agent can be thermally cured at 150° C. or less, and therefore, the possibility of affecting the organic EL element during the surface sealing becomes low. On the other hand, when the reaction activity-development temperature is 70° C. or more, unnecessary curing reaction of the cationic polymerizable compounds (components (B) and (A)) becomes less likely to occur during storage of the surface sealing agent, and therefore, the storage stability becomes satisfactory.

The reaction activity-development temperature may be defined as a rising peak temperature of the exothermic peak measured by differential scanning calorimetry (DSC). The reaction activity-development temperature may be adjusted, preferably by the structure of the quaternary ammonium ion contained in the thermal cationic polymerization initiator (C).

The cured product of the surface sealing agent preferably has a high transmittance for visible light. With respect to a cured film obtained by curing the surface sealing agent having a film thickness of 10 μm at 100° C. for 30 minutes, the parallel light transmittance of the cured film at a wavelength of 380 nm (visible light, ultraviolet light) is preferably 80% or more, more preferably 90% or more, and still more preferably 95% or more. When the parallel light transmittance is 80% or more, light emitted from an organic EL element can be efficiently outputted through the cured product of the surface sealing agent. However, when the surface sealing agent is used for a back emission type organic EL element, the transparency of the cured product is not particularly limited. The parallel light transmittance of the cured product can be measured in accordance with JIS K 7136 and JIS K 7361-1 using automatic haze meter TC-H III DPK manufactured by Tokyo Denshoku. Co., Ltd.

The surface sealing agent can be manufactured, for example, by mixing each of the above mentioned components in an inert gas atmosphere at a temperature (e.g., 60° C. or lower) which is lower than the reaction activity-development temperature. The mixing of each component can be performed by a method in which each of the components is charged in a flask, followed by stirring; a method in which kneading is carried out with a three-roll mill; or the like.

The surface sealing agent is preferably used as a surface sealing agent for an organic EL element, but it can be also used as various sealing agents (e.g., a sealing agent for an LED element and a liquid crystal sealant) or as a transparent film material.

2. Organic EL Device

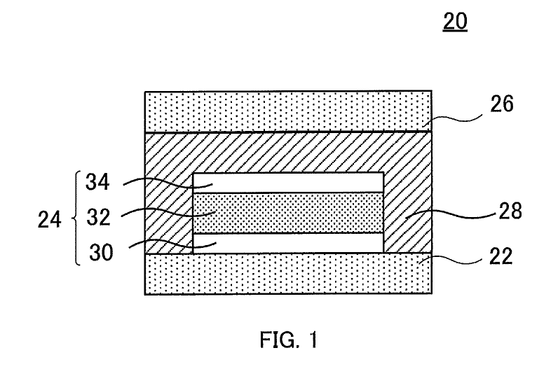

FIG. 1 is a schematic view illustrating an example of an organic EL device which may constitute an organic EL panel. As shown in FIG. 1, organic EL device 20 includes display substrate 22 having organic EL element 24 disposed thereon, counter substrate 26, and sealing member 28 which is disposed at least between the organic EL element 24 and the counter substrate 26 and which is sealing the organic EL element 24. The sealing member 28 covers (surface-seals) the periphery of the organic EL element 24, and is composed of a cured product of the surface sealing agent of the present invention.

Generally, display substrate 22 and counter substrate 26 may be a glass substrate, a resin film or the like. At least one of display substrate 22 and counter substrate 26 may be a transparent glass substrate or a transparent resin film. Examples of the transparent resin films include films of aromatic polyester resins, such as a polyethylene terephthalate.

When organic EL element 24 is a top emission type, organic EL element 24 includes, from the display substrate 22 side, pixel electrode layer 30 (made of aluminum, silver or the like), organic EL layer 32, and counter electrode layer 34 (made of ITO (oxide of indium and tin), IZO (oxide of indium and zinc) or the like). Pixel electrode layer 30, organic EL layer 32, and counter electrode layer 34 may be formed by vacuum deposition, sputtering or the like.

The organic EL device may be manufactured, for example, through the steps of: 1) preparing an organic EL element disposed on a substrate, 2) covering the organic EL element with a surface sealing agent, and 3) thermally curing the surface sealing agent. The coverage of the organic EL element with a surface sealing agent can be performed by either coating with a surface sealing agent in a liquid form, or by thermocompression bonding of a surface sealing agent in a solid form (sheet form).

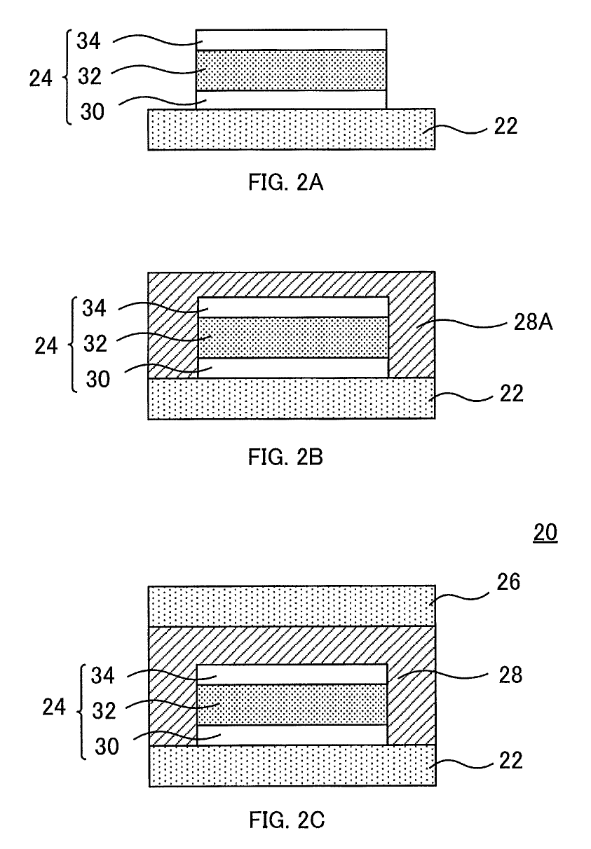

FIGS. 2A to 2C are schematic views illustrating an example of a process for manufacturing an organic EL device. Organic EL device 20 may be manufactured through the steps of: 1) preparing display substrate 22 having organic EL element 24 laminated thereon (FIG. 2A), 2) coating organic EL element 24 with the surface sealing agent of the present invention to form coating film 28A of the surface sealing agent (FIG. 2B), and 3) disposing counter substrate 26 on coating film 28A of the surface sealing agent, and thermally curing the coating film 28A of the surface sealing agent to form sealing member 28 and bond counter substrate 26 (FIG. 2C). Organic EL device 20 can be thus obtained.

The coating of the surface sealing agent can be performed by a technique such as screen printing, dispenser coating, slit coating or spray coating.

The thermal curing of the surface sealing agent can be performed at a relatively low temperature. The thermal curing temperature may be any temperature where the thermal cationic polymerization initiator (C) in the surface sealing agent becomes activated, and is preferably 70 to 150° C., more preferably 80 to 110° C., and still more preferably 90 to 100° C. When the thermal curing temperature is 70° C. or higher, the thermal cationic polymerization initiator (C) is easily activated to a degree sufficient for enabling a satisfactory curing of the cationic polymerizable compound, such as the component (B) and the component (A). When the thermal curing temperature is 150° C. or lower, the possibility of affecting the organic EL element during the thermal curing becomes lowered.

Thermal curing can be performed by a method known in the art such as heating in an oven or on a hot plate. Heating time is preferably 10 to 120 minutes, more preferably 20 to 90 minutes, and still more preferably 30 to 60 minutes.

The thickness of sealing member 28 may be any thickness sufficient for covering organic EL element 24, and may be, e.g., about 0.1 to 20 μm.

Sealing member 28 may have, as necessary, a passivation film formed on sealing member 28. The passivation film may cover the entire surface of sealing member 28 or only a part of the surface. The passivation film may be, for example, an inorganic compound film formed by plasma CVD method. The material of the passivation film is preferably a transparent inorganic compound, and examples thereof include, but are not particularly limited to, silicon nitride, silicon oxide, SiONF, and SiON. The thickness of the passivation film is preferably 0.1 to 5 μm.

As described above, the surface sealing agent of the present invention contains the cationic polymerizable compound (B) having a (poly)oxyalkylene structure and the leveling agent (D), and therefore, during the thermal curing of the surface sealing agent, it becomes possible to prolong the time in which the surface sealing agent is capable of flowing. As a result, during the thermal curing of the surface sealing agent, it becomes possible to prolong the working time of the leveling agent (D), thereby forming on an organic EL element a sealing member made of a cured product layer which shows low occurrence of irregularity and cissing and has high surface smoothness.

Further, in the first surface sealing agent, the cationic polymerizable compound (B) having a (poly)oxyalkylene structure has a structure similar to that of the cationic polymerizable compound (A), and therefore, it is highly compatible with the cationic polymerizable compound (A). The second surface sealing agent does not necessarily contain the cationic polymerizable compound (A). Accordingly, it becomes possible to achieve high storage stability by suppressing compatibility defect between the cationic polymerizable compound (B) having a (poly)oxyalkylene structure and the cationic polymerizable compound (A) and the precipitation resulting therefrom.

### Examples

Hereinafter, the present invention is described with reference to Examples, which however shall not be construed as limiting the technical scope of the present invention.

1. Materials for Surface Sealing Agent

(A) Cationic Polymerizable Compound
YL983U, manufactured by Mitsubishi Chemical Corporation:
   Bisphenol F type epoxy resin (weight average molecular weight: 338, epoxy equivalent: 165 to 175 g/eq, E-type viscosity (at 25° C., 2.5 rpm): 3,000 to 4,000 mPa·s, bifunctional).

(B) Cationic Polymerizable Compound having (Poly)oxyalkylene Structure
Denacol EX-171, manufactured by Nagase ChemteX Corporation:
   Lauryl alcohol (EO)₁₅ glycidyl ether, epoxy equivalent: 971 g/eq, monofunctional, weight average molecular weight: 971, n=15 and R=ethylene group in formula (1).
Denacol EX-145, manufactured by Nagase ChemteX Corporation:
   Phenol (EO)₅ glycidyl ether, epoxy equivalent: 400 g/eq, monofunctional, weight average molecular weight: 400, n=5 and R=ethylene group in formula (1).
Denacol EX-861, manufactured by Nagase ChemteX Corporation:
   Polyethylene glycol diglycidyl ether, epoxy equivalent: 551 g/eq, bifunctional, weight average molecular weight: 1102, n=22 and R=ethylene group.
RIKARESIN BEO-60E, manufactured by New Japan Chemical Co., Ltd.:
   Bisphenol A bis(triethylene glycol glycidyl ether) ether, epoxy equivalent: 345 to 385 g/eq, bifunctional, weight average molecular weight: 690 to 770, n≦5 and R=ethylene group.

(C) Thermal Cationic Polymerization Initiator
CXC-1612, manufactured by King Industries, Inc.:
   Quaternary ammonium salt represented by the following formula:

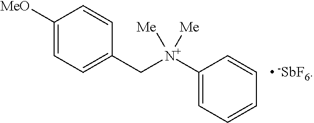

CXC-1738, manufactured by King Industries, Inc.:
   Quaternary ammonium salt of the above formula which has “PF₆⁻” as a counter ion.
CXC-1821, manufactured by King Industries, Inc.:
   Quaternary ammonium salt of the above formula which has a counter ion represented by the following formula:

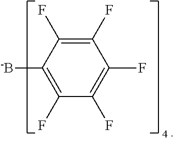

(D) Leveling Agent
LS-460, manufactured by Kusumoto Chemicals, Ltd.: Silicone-based polymer

(Compound for Comparison)
PEG#6000: Polyethylene glycol, weight average molecular weight: 8450

2. Production of Surface Sealing Agent

### Example 1

In a flask purged with nitrogen, 100 parts by mass of an epoxy resin (YL983U) as the component (A), 2 parts by mass of a quaternary ammonium salt (CXC-1612) as the component (B), 2 parts by mass of EX-861 as the component (C), and 0.3 parts by mass of the leveling agent (LS-460) as the component (D) were stirred and mixed at 50° C. to obtain a surface sealing agent.

### Examples 2 to 12

Surface sealing agents were produced in substantially the same manner as in Example 1 except that the compositions were changed as shown in Tables 1 and 2.

### Comparative Example 1

A surface sealing agent was produced in substantially the same manner as in Example 1 except that the component (B) was omitted.

### Comparative Example 2

A surface sealing agent was produced in substantially the same manner as in Example 1 except that the component (C) was omitted.

### Comparative Examples 3 and 4

Surface sealing agents were produced in substantially the same manner as in Example 1 except that the type and content of the component (B) were changed as shown in Table 2.

The viscosity and storage stability of the produced surface sealing agents, and the surface smoothness of cured surface sealing agents were evaluated by the following methods. Further, regarding the surface sealing agent produced in Example 1, the parallel light transmittance of the cured product was also measured.

(Viscosity)

The viscosity of the produced surface sealing agent was measured by an E-type viscometer (RC-500, manufactured by Toki Sangyo Co., Ltd.) at 25° C. and 2.5 rpm.

(Storage Stability)

A prescribed amount of the produced surface sealing agent was sampled and stored at −10° C. for 7 days. The stored surface sealing agent was visually observed and evaluated for the occurrence of cloudiness. A surface sealing agent which did not become clouded and maintained its appearance after storage was evaluated as B, and a surface sealing agent which became clouded was evaluated as C. Cloudiness is considered to occur by precipitation of the component (B) due to its poor compatibility with the component (A).

(Surface Smoothness of Cured Product Layer)

The produced surface scaling agent was printed onto a glass substrate (7 cm×7 cm×0.7 mm in thickness) subjected to washing by ozone treatment. The printing was performed using a screen printer (Screen Printer Model 2200, manufactured by MITANI Micronics Co., Ltd.). The coating of the surface sealing agent was performed so that the surface sealing agent in a dry state has a size of 5 cm×5 cm and a thickness of 10 μm. The glass substrate having the printed surface sealing agent thereon was heated on a hot plate at 100° C. for 30 minutes to obtain a sample of a cured product layer. The obtained cured product layer was visually observed.

A cured product layer having a smooth surface without coating defects (cissing) and irregularity is evaluated as A; a cured product layer having a smooth surface, but with some coating defects (cissing) and irregularity is evaluated as B; and a cured product layer having unsmooth surface and with coating defects (cissing) and irregularity is evaluated as C.

(Parallel Light Transmittance) A cured product was produced in the same manner as the above mentioned sample of a cured product layer used for evaluating the surface smoothness. The parallel light transmittance (%) of the thus produced cured product at a wavelength of 380 nm was measured using automatic haze meter TC-H III DPK manufactured by Tokyo Denshoku. Co., Ltd. A glass substrate used for printing was used as a reference.

The evaluation results of Examples 1 to 8 are shown in Table 1, and the evaluation results of Examples 9 to 12 and Comparative Examples 1 to 4 are shown in Table 2. In the tables, the unit for the numbers in the rows showing the composition is “part(s) by mass.”

TABLE 1

| | | | Ex. 1 | Ex. 2 | Ex. 3 | Ex. 4 | Ex. 5 | Ex. 6 | Ex. 7 | Ex. 8 |
|---|---|---|---|---|---|---|---|---|---|---|
| Composition | (A) Cationic | YL983U | 100 | 100 | 100 | 100 | 50 | | 100 | 100 |
| | Polymerizable | | | | | | | | | |
| | Compound | | | | | | | | | |
| | (B) Cationic | EX-861 | 2 | | | | | | 0.1 | 1 |
| | Polymerizable | (Bifunctional, | | | | | | | | |
| | Compound | n = 22) | | | | | | | | |
| | Containing | EX-171 | | 2 | | | | | | |
| | (Poly)oxyalkylene | (Monofunctional, | | | | | | | | |
| | | n = 15) | | | | | | | | |
| | | EX-145 | | | 2 | | | | | |
| | | (Monofunctional, | | | | | | | | |
| | | n = 5) | | | | | | | | |
| | | BEO-60E | | | | 2 | 50 | 100 | | |
| | | (Bifunctional, | | | | | | | | |
| | | n ≦ 5) | | | | | | | | |
| | PEG#6000 | | | | | | | | | |
| | (C) Thermal Cationic | CXC-1612 | 2 | 2 | 2 | 2 | 2 | 2 | 2 | 2 |
| | Polymerization Initiator | CXC-1738 | | | | | | | | |
| | | CXC-1821 | | | | | | | | |
| | (D) Leveling Agent | LS-460 | 0.3 | 0.3 | 0.3 | 0.3 | 0.3 | 0.3 | 0.3 | 0.3 |

| | | | | | | | | | |
|---|---|---|---|---|---|---|---|---|---|
| | Corresponding Embodiment | First | First | First | First | First, | Second | First | First |
| | | | | | | Second | | | |
| Physical | Viscosity/mPa · s | 2,400 | 3,400 | 2,200 | 2,900 | 2,300 | 1,600 | 3,000 | 2,600 |
| Properties | Surface Smoothness of Cured Product Layer | B | B | B | B | A | A | B | B |
| | Storage Stability | B | B | B | B | B | B | B | B |

TABLE 2

| | | | | | | | Comp. | Comp. | Comp. | Comp. |
|---|---|---|---|---|---|---|---|---|---|---|
| | | | Ex. 9 | Ex. 10 | Ex. 11 | Ex. 12 | Ex. 1 | Ex. 2 | Ex. 3 | Ex. 4 |
| Composition | (A) Cationic | YL983U | 100 | 100 | 100 | 100 | 100 | 100 | 100 | 100 |
| | Polymerizable | | | | | | | | | |
| | Compound | | | | | | | | | |
| | (B) Cationic | EX-861 | 5 | 10 | 2 | 2 | | 2 | | |
| | Polymerizable | (Bifunctional, | | | | | | | | |
| | Compound | n = 22) | | | | | | | | |
| | Containing | EX-171 | | | | | | | | |
| | (Poly)oxyalkylene | (Monofunctional, | | | | | | | | |
| | | n = 15) | | | | | | | | |
| | | EX-145 | | | | | | | | |
| | | (Monofunctional, | | | | | | | | |
| | | n = 5) | | | | | | | | |
| | | BEO-60E | | | | | | | | |
| | | (Bifunctional, | | | | | | | | |
| | | n ≦ 5) | | | | | | | | |
| | PEG#6000 | | | | | | | | 5 | 10 |
| | (C) Thermal Cationic | CXC-1612 | 2 | 2 | | | 2 | 2 | 2 | 2 |
| | Polymerization Initiator | CXC-1738 | | | 2 | | | | | |
| | | CXC-1821 | | | | 2 | | | | |
| | (D) Leveling Agent | LS-460 | 0.3 | 0.3 | 0.3 | 0.3 | 0.3 | | 0.3 | 0.3 |

| | | | | | | | | | |
|---|---|---|---|---|---|---|---|---|---|
| | Corresponding Embodiment | First | First | First | First | — | — | — | — |
| Physical | Viscosity/mPa · s | 2,100 | 1,800 | 2,500 | 2,400 | 2,500 | 2,400 | 2,700 | 2,800 |
| Properties | Surface Smoothness of Cured Product Layer | A | A | B | B | C | C | A | A |
| | Storage Stability | B | B | B | B | B | B | C | C |

Tables 1 and 2 show that the cured product layers formed from the surface sealing agents of Examples 1 to 12, each containing both components (B) and (D), have high surface smoothness without coating defects (cissing) and irregularity. It is considered that such excellent results are achieved as follows. During thermal curing of the surface sealing agent, the polyoxyalkylene structure of the component (B) scavenged cations of the thermal cationic polymerization initiator, namely component (C), and delayed either the cationic polymerization of the component (A) (Examples 1 to 5 and 7 to 12) or the cationic polymerization of the component (B) (Example 6), while allowing the leveling agent, namely the component (D), to satisfactorily exhibit its function during this delay. Further, the surface sealing agents of Examples 1 to 12 all show high storage stability.

On the other hand, the cured product layers of the surface sealing agents of Comparative Examples 1 and 2, not containing either the component (B) or component (D), have low surface smoothness with coating defects (cissing) and irregularity. It is considered that, in these Comparative Examples, satisfactory leveling of the surface sealing agents was not achieved because the surface sealing agent of Comparative Example 1 was incapable of achieving a satisfactory polymerization delaying effect due to lack of component (B), and the surface sealing agent of Comparative Example 2 did not contain the component (D). Further, the surface sealing agents of Comparative Examples 3 and 4, which contain a polyether compound in place of the component (B), had low storage stability. The cause of such a low storage stability is considered to be the polyether compound having a large molecular weight which does not dissolve in the component (A).

Comparisons among Examples 7 to 10 show that further improvements in the surface smoothness of the cured product layer can be achieved by increasing the content of the component (B), based on 100 parts by mass of the component (A1). Further, comparisons among Examples 4 to 6 show that further improvements in the surface smoothness of the cured product layer can be achieved by using the component (B1) as a major component.

Furthermore, it has been confirmed that the parallel light transmittance of the cured product of the surface sealing agent of Example 1 at a wavelength of 380 nm was 98%, which is a satisfactorily high value.

This application claims priority based on Japanese Patent Application No. 2014-249034, filed on Dec. 9, 2014, the entire contents of which including the specification and the drawings are incorporated herein by reference.

### INDUSTRIAL APPLICABILITY

The present invention can provide a surface sealing agent which has high storage stability, and which can form a cured product layer on an object to be coated, such as an organic EL element. The formed cured product layer shows low occurrence of irregularity and cissing and has high surface smoothness.

### REFERENCE SIGNS LIST

20 Organic EL device
22 Display substrate
24 Organic EL element
26 Counter substrate
28A Coating film of surface sealing agent
28 Sealing member
30 Pixel electrode layer
32 Organic EL layer
34 Counter electrode layer

1. A surface sealing agent for an organic EL element, comprising:
(B) a cationic polymerizable compound having a cationic polymerizable functional group per molecule, and also having a structure represented by following formula (1):
—(R—O)ₙ— Formula (1)
wherein:
R represents an alkylene group having 2 to 5 carbon atoms and
n represents an integer of 1 to 150;
(C) a thermal cationic polymerization initiator; and
(D) a leveling agent.

2. The surface sealing agent for an organic EL element according to claim 1, wherein the component (B) is represented by formula (1) in which R is an ethylene group and n is 2 or more.

3. The surface sealing agent for an organic EL element according to claim 1, wherein weight average molecular weight of the component (B) is 250 to 10,000.

4. The surface sealing agent for an organic EL element according to claim 1, further comprising:
(A1) a cationic polymerizable compound (exclusive of the component (B)) having two or more cationic polymerizable functional groups per molecule.

5. The surface sealing agent for an organic EL element according to claim 4, wherein the component (A1) has a bisphenol structure.

6. The surface sealing agent for an organic EL element according to claim 4, comprising 0.1 to 120 parts by mass of the component (B), based on 100 parts by mass of the component (A1).

7. The surface sealing agent for an organic EL element according to claim 4, comprising:
0.1 to 5 parts by mass of the component (C), and
0.01 to 1 part by mass of the component (D),
each based on 100 parts by mass of a total of the components (A1) and (B).

8. The surface sealing agent for an organic EL element according to claim 1, wherein:
the component (B) is (B1) a cationic polymerizable compound having two or more cationic polymerizable functional groups per molecule, and
the surface sealing agent optionally comprises (A) a cationic polymerizable compound (exclusive of the component (B)) having a cationic polymerizable functional group per molecule.

9. The surface sealing agent for an organic EL element according to claim 8, wherein the component (B1) has a bisphenol structure.

10. The surface sealing agent for an organic EL element according to claim 8, comprising 0.1 to 120 parts by mass of the component (A), based on 100 parts by mass of the component (B1).

11. The surface sealing agent for an organic EL element according to claim 8, comprising:
0.1 to 5 parts by mass of the component (C), and
0.01 to 1 parts by mass of the component (D),
each based on 100 parts by mass of a total of the components (B1) and (A).

12. The surface sealing agent for an organic EL element according to claim 1, wherein the component (D) is at least one member selected from the group consisting of a silicone-based polymer and an acrylate-based polymer.

13. The surface sealing agent for an organic EL element according to claim 1, wherein the cationic polymerizable functional group is at least one member selected from the group consisting of an epoxy group, an oxetanyl group and a vinyl ether group.

14. The surface sealing agent for an organic EL element according to claim 1, wherein the component (C) is an onium salt.

15. The surface sealing agent for an organic EL element according to claim 1 having a viscosity of 50 to 30,000 mPa·s, as measured by an E-type viscometer at 25° C. and 2.5 rpm.

16. The surface sealing agent for an organic EL element according to claim 1 which is in a sheet form.

17. A cured product of the surface sealing agent for an organic EL element according to claim 1.
